(19) United States
(12) Patent Application Publication
(10) Pub. No.: US 2016/0135311 A1
(43) Pub. Date: May 12, 2016

(54) SUPPORTING DEVICE AND SUPPORTING ASSEMBLY

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventors: MEI-HUA LIU, Shenzhen (CN); TE-HSU WANG, New Taipei (TW); CHIH-KANG CHO, New Taipei (TW)

(21) Appl. No.: 14/568,906

(22) Filed: Dec. 12, 2014

(30) Foreign Application Priority Data
Nov. 10, 2014 (CN) 201410627040.9

(51) Int. Cl. H05K 5/02; H05K 5/00; F16M 11/26

(52) U.S. Cl. CPC H05K 5/0234; F16M 11/26; H05K 5/0017

(57) ABSTRACT

A supporting device is used to support a display. The supporting device includes two fixing parts, two supporting arms, and a base. The base can be made by bending a rod in a plane. The fixing parts are fixed with the display. Each supporting arm includes a connecting portion and an assembly portion. The connecting portion connects an end of the fixing part. The assembly portion is fixed with the base. An extending direction of the supporting arm is substantially perpendicular to the plane with the rod.

### CROSS-REFERENCE TO RELATED APPLICATIONS

This application claims priority to Chinese Patent Application No. 201410627040.9 filed on Nov. 10, 2014, the contents of which are incorporated by reference herein.

### FIELD

The subject matter herein generally relates to supporting devices with supporting assemblies.

### BACKGROUND

Electronic devices such as displays include supporting brackets to support the display on a platform. A conventional supporting bracket usually includes a supporting panel mounted to a back of the display, and a stand on the platform.

### BRIEF DESCRIPTION OF THE DRAWINGS

Implementations of the present technology will now be described, by way of example only, with reference to the attached figures.

FIG. 1 is an exploded, isometric view of one embodiment of a supporting device.

FIG. 2 is an assembled view of the supporting device of FIG. 1.

FIG. 3 is an assembled view of another embodiment of the supporting device of FIG. 1.

FIG. 4 is another assembled view of the supporting device of FIG. 3, but viewed from another angle.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure is described in relation to a supporting device.

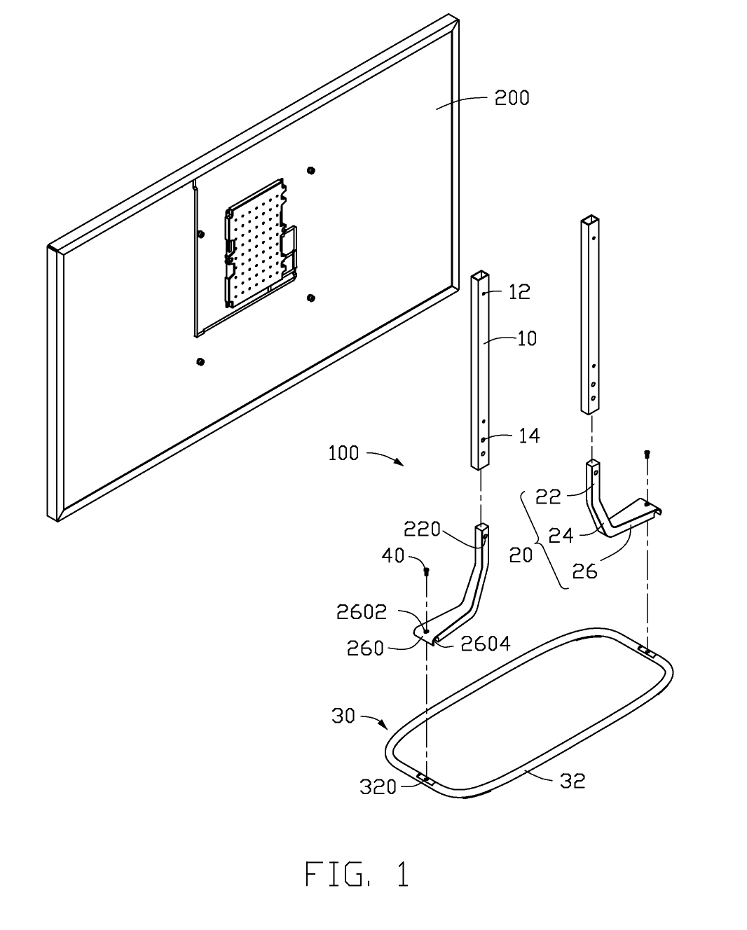

FIG. 1 illustrates one embodiment of a supporting device 100 for supporting a display 200. The supporting device 100 includes two fixing parts 10, two supporting arms 20, a base 30, and a plurality of bolts 40. Each fixing part 10 defines two assembly holes 12 and two fixing holes 14. The two fixing holes 14 are defined in an end of the fixing part 10. The fixing part 10 is substantially rectangular and hollow. The fixing part 10 can be made of aluminium alloy.

The supporting arm 20 includes a connecting portion 22, a bending portion 24, and an assembly portion 26. The bending portion 24 extends from the connecting portion 22. The assembly portion 26 extends from the bending portion 24. The bending portion 24 is located between the connecting portion 22 and the assembly portion 26. Each connecting portion 22 defines a connecting hole 220. The connecting hole 220 is defined in an end of the connecting portion 22, away from the bending portion 24. A cross-sectional area of the connecting portion 22 is smaller than a cross-sectional area of the fixing part 10. The assembly portion 26 includes a locking end 260 away from the bending portion 24. The locking end 260 is substantially arcuate. The locking end 260 defines an assembly groove 2604. The assembly groove 2604 is substantially arcuate. The locking end 260 further defines a through hole 2602. The through hole 2602 communicates with the assembly groove 2604. The supporting arm 20 can be made of aluminium alloy.

The base 30 includes a rod 32 and four gaskets 34. The rod 32 can be made of stainless steel. The rod 32 is bent in one plane to form the base 30. The base 30 is substantially rectangular. The rod 32 is partially hollowed. Each side of the rod 32 defines a threaded hole 320. The four gaskets 34 are fixed in the four corners of the rod 32. The four gaskets 34 are elastic.

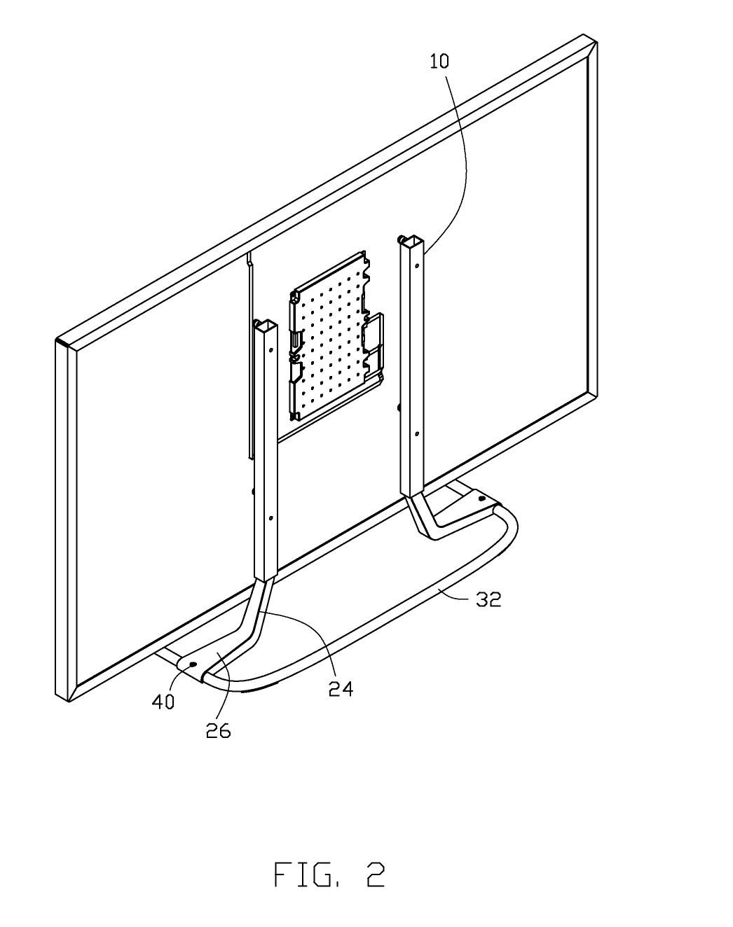

FIG. 2 shows a view of the assembled supporting device 100. In assembly, two fixing parts 10 are fixed to the display 200 by the assembly holes 12. The two fixing parts 10 are substantially parallel to each other. The portion with the threaded hole 320 of the rod 32 is received in the assembly groove 2604 of the supporting arm 20. The threaded hole 320 and the through hole 2602 are vertically aligned. The bolt 40 passes from the through hole 2602 into the threaded hole 320. The bolt 40 is fixed with the threaded hole 320 to fix the supporting arm 20 with the base 30. An extending direction of the supporting arm 20 is substantially perpendicular to the plane with the rod 32. The base 30 is located on a plane. The connecting portion 22 of the supporting arm 20 is received in the fixing part 10. An end of the fixing part 10 abuts the bending portion 24 to support the display 200. The fixing part 10 is substantially perpendicular to the plane with the rod 32.

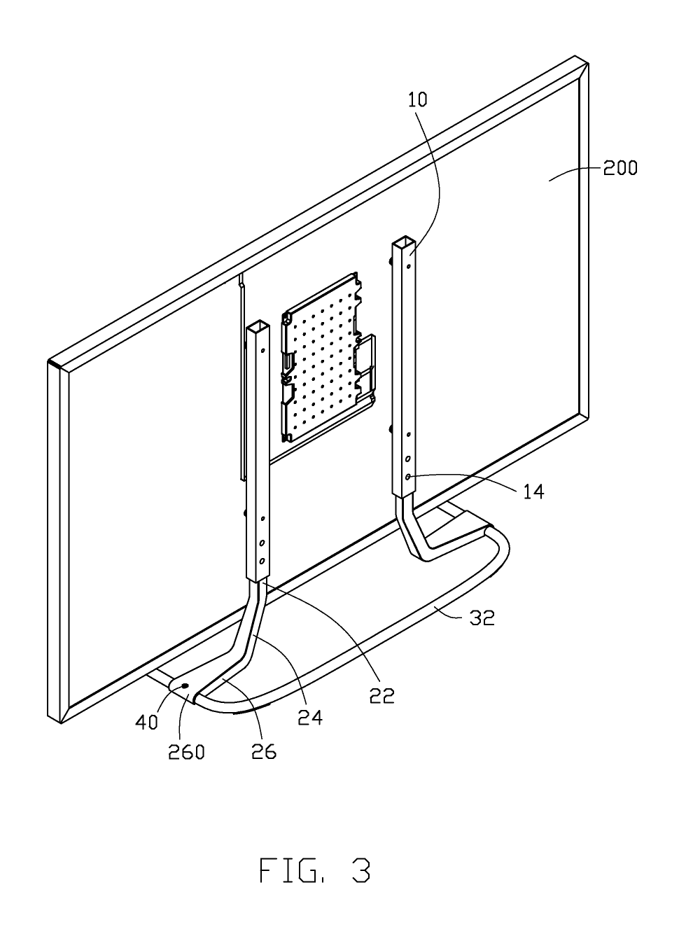

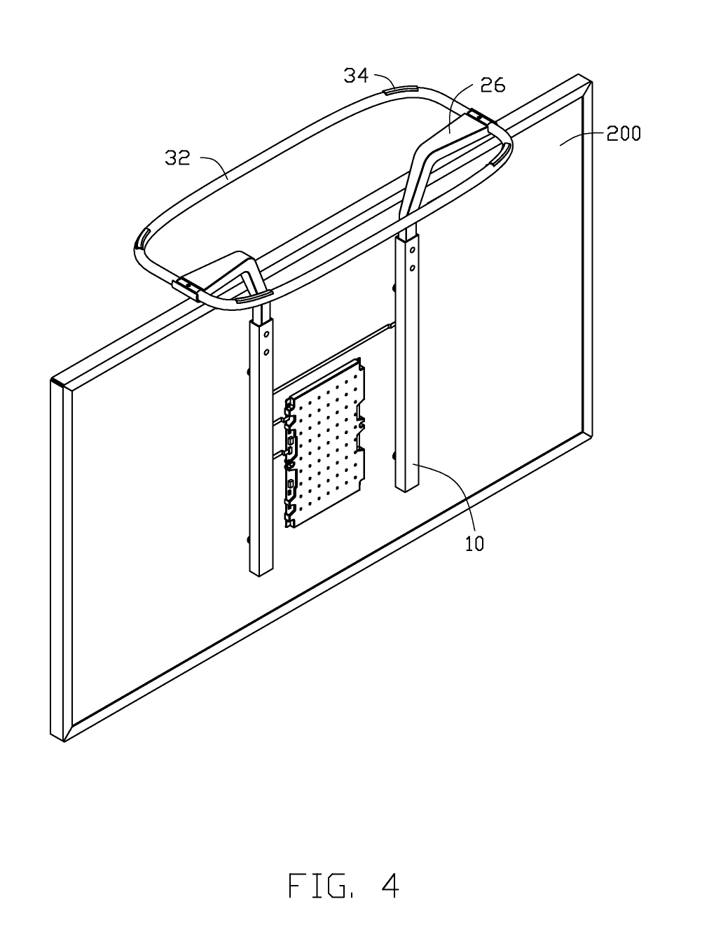

FIGS. 3 and 4 show views of the assembled supporting device 100 in another embodiment. In assembly, the two fixing parts 10 are fixed with the display 200 by the assembly holes 12. The two fixing parts 10 are substantially parallel to each other. The portion with the threaded hole 320 of the rod 32 is received in the assembly groove 2604 of the supporting arm 20. The threaded hole 320 and the through hole 2602 are vertically aligned. The bolt 40 extends into the threaded hole 320 from the through hole 2602. The bolt 40 is fixed with the threaded hole 320 to fix the supporting arm 20 with the base 30. An extending direction of the supporting arm 20 is substantially perpendicular to the plane with the rod 32. The base 30 is located on a plane. The connecting portion 22 of the supporting arm 20 is received in the fixing part 10. The connecting hole 220 of the supporting arm 20 is fixed with one of the two fixing holes 14 to fix the supporting arm 20 with the fixing part 10. The connecting hole 220 of the supporting arm 20 can be fixed with different fixing holes 14 to adjust a height of the display 200. The four gaskets 34 abut the plane to prevent abrasion of the rod 32.

The embodiments shown and described above are only examples. Many details are often found in the art such as the other features of a supporting device. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

1. A supporting device for supporting a display, the supporting device comprising:
two fixing parts fixed with the display;
two supporting arms, each supporting arm comprising a connecting portion, an assembly portion, and a bending portion slantingly connected between the connecting portion and the assembly portion, wherein tops ends of the bending portions slantingly extend toward each other and are connected to the connecting portions, the connecting portions of the two supporting arms are received in the fixing parts, and bottom ends of the fixing parts abut the bending portions of the two supporting arms; and
a base comprising a rod, the base formed from the rod in a plane;
wherein each connecting portion connects to an end of the fixing part, the assembly portion is fixed with the base, and an extending direction of the supporting arm is substantially perpendicular to the plane with the rod.

2. (canceled)

3. The supporting device of claim 1, wherein the fixing part defines a fixing hole, the connecting portion defines a connecting hole, the fixing part is fixed with the connecting portion by the fixing hole and the connecting hole.

4. The supporting device of claim 1, wherein the fixing part defines two fixing holes, the connecting portion defines a connecting hole, the connecting hole can be fixed with different fixing holes to adjust a height of the display.

5. The supporting device of claim 1, wherein two fixing parts are substantially parallel to each other.

6. The supporting device of claim 1, wherein the assembly portion defines an assembly groove, the assembly groove is substantially arcuate, the base is partly received in the assembly groove.

7. The supporting device of claim 6, wherein the assembly portion further defines a through hole, the through hole communicates with the assembly groove, the base defines two threaded holes, a bolt extends into the threaded hole from the through hole, and the bolt is fixed with the threaded hole to fix the supporting arm to the base.

8. The supporting device of claim 1, wherein the fixing part is substantially rectangular and hollow, and the fixing part is made of aluminium alloy.

9. The supporting device of claim 1, wherein the base is substantially rectangular, and the rod is made of stainless steel.

10. A supporting assembly comprising:
a display;
two fixing parts fixed with the display;
two supporting arms, each supporting arm comprising a connecting portion, an assembly portion, and a bending portion slantingly connected between the connecting portion and the assembly portion, wherein tops ends of the bending portions slantingly extend toward each other and are connected to the connecting portions, the connecting portions of the two supporting arms are received in the fixing parts, and bottom ends of the fixing parts abut the bending portions of the two supporting arms; and
a base comprising a rod, the base formed from the rod in a plane;
wherein each connecting portion connects to an end of the fixing part, the assembly portion is fixed with the base, and an extending direction of the supporting arm is substantially perpendicular to the plane with the rod.

11. (canceled)

12. The supporting assembly of claim 10, wherein the fixing part defines a fixing hole, the connecting portion defines a connecting hole, and the fixing part is fixed with the connecting portion by the fixing hole and the connecting hole.

13. The supporting assembly of claim 10, wherein the fixing part defines two fixing holes, the connecting portion defines a connecting hole, the connecting hole can be fixed with different fixing holes to adjust a height of the display.

14. The supporting assembly of claim 10, wherein two fixing parts are substantially parallel to each other.

15. The supporting assembly of claim 10, wherein the assembly portion defines an assembly groove, the assembly groove is substantially arcuate, the base is partly received in the assembly groove.

16. The supporting assembly of claim 15, wherein the assembly portion further defines a through hole, the through hole communicates with the assembly groove, the base defines two threaded holes, a bolt extends into the threaded hole from the through hole, and the bolt is fixed with the threaded hole to fix the supporting arm to the base.

17. The supporting assembly of claim 10, wherein the fixing part is substantially rectangular and hollow, and the fixing part is made of aluminium alloy.

18. The supporting assembly of claim 10, wherein the base is substantially rectangular, and the rod is made of stainless steel.
